(19) United States
(12) Patent Application Publication
(10) Pub. No.: US 2015/0279463 A1
(43) Pub. Date: Oct. 1, 2015

(54) ADJUSTABLE NON-VOLATILE MEMORY REGIONS OF DRAM-BASED MEMORY MODULE

(71) Applicant: DELL PRODUCTS, L.P., Round Rock, TX (US)

(72) Inventor: Stuart A. BERKE, Austin, TX (US)

(73) Assignee: DELL PRODUCTS, L.P., Round Rock, TX (US)

(21) Appl. No.: 14/230,911

(22) Filed: Mar. 31, 2014

(51) Int. Cl. G11C 14/00; G11C 7/10

(52) U.S. Cl. CPC G11C 14/0018; G11C 7/1072; G11C 16/0483

(57) ABSTRACT

An information handling system and method provide for: electrically powering, with a primary power source and an independent power source, a dynamic random access memory (DRAM) module having an amount of memory space that is addressed by a host processor of an information handling system; measuring an energy capacity value of the independent energy storage device; determining a persistent value corresponding to a fraction of the memory space of the DRAM module that can be protected based at least in part on the measured energy capacity value of the independent energy storage device; reporting the persistent value to the host processor; and communicating by the host processor to the DRAM module a dynamic assignment of persistent and non-persistent memory allocations in accordance to the fraction of the memory space of the DRAM module that can be protected in an event of loss of the primary power source.

### BACKGROUND

1. Technical Field

The present disclosure generally relates to an information handling system and in particular to a dynamic random access memory (DRAM)-based non-volatile memory module that is capable of being powered by an independent energy storage device.

2. Description of the Related Art

As the value and use of information continues to increase, individuals and businesses seek additional ways to process and store information. One option available to these users is an information handling system (IHS). An IHS generally processes, compiles, stores, and/or communicates information or data for business, personal, or other purposes thereby allowing users to take advantage of the value of the information. Because technology and information handling needs and requirements vary between different users or applications, IHSs may vary with respect to the type of information handled; the methods for handling the information; the methods for processing, storing or communicating the information; the amount of information processed, stored, or communicated; and the speed and efficiency with which the information is processed, stored, or communicated. The variations in IHSs allow for IHSs to be general or configured for a specific user or specific use such as financial transaction processing, airline reservations, enterprise data storage, or global communications. In addition, IHSs may include or comprise a variety of hardware and software components that may be configured to process, store, and communicate information and may include one or more computer systems, data storage systems, and networking systems.

IHSs often rely upon dynamic random access memory (DRAM) as a higher performance alternative to non-volatile memory. However, loss of a primary power source to the DRAM or a system fault can cause an unacceptable loss of data or interruption to a process. Examples of such usage models that require memory persistence include caching, metadata, persistent in-memory data, logging, journaling, indexing, hashing, checkpointing/snapshotting, and non-volatile write caching for a software redundant array of independent disks (RAID). Some information systems include a large backup power system to maintain full system functionality in the event of loss of a primary power source. However, some IHS applications require much smaller physical dimensions that cannot support a full-system backup power source.

Alternatively, some IHSs include one or more hybrid memory modules of DRAM along with non-volatile memory. The DRAM is protected for a period of time by a dedicated, independent energy storage device sufficient to save to the non-volatile memory. However, similar physical constraints exist. As the memory capacity increases for the DRAM, the size of a dedicated, independent energy storage device such as batteries or ultracapacitors necessarily increases. In addition, such energy storage devices tend to degrade with time.

### BRIEF SUMMARY

According to at least one aspect of the present disclosure, an information handling system (IHS) includes at least one dynamic random access memory (DRAM) module having a memory space addressed by the host processor. The IHS includes an independent energy storage device electrically connected to the at least one DRAM module. The IHS includes an energy test component that measures an energy capacity value for the independent energy storage device. A controller of the IHS determines a persistent value corresponding to a fraction of the memory space of the at least one DRAM module that can be protected. The persistant value is based at least in part upon the measured energy capacity value for the independent energy storage device. The controller reports the persistent value to the host processor. The IHS includes a host processor powered by a primary power source. The host processor communicates to the at least one DRAM module a dynamic assignment of persistent and non-persistent memory allocations. The dynamic assignment is in accordance to the fraction of the memory space of the at least one DRAM module that can be protected in an event of loss of the primary power source.

According to at least one aspect of the present disclosure, a method includes electrically powering, with a primary power source and an independent power source, at least one DRAM module having a memory space that is addressed by a host processor of an IHS. The method includes measuring an energy capacity value of the independent energy storage device. The method includes determining a persistent value corresponding to a fraction of the memory space of the at least one DRAM module that can be protected based at least in part on the measured energy capacity value of the independent energy storage device. The method includes reporting the persistent value to the host processor. The method includes the host process communicating to the at least one DRAM module a dynamic assignment of persistent and non-persistent memory allocations in accordance to the fraction of the memory space of the at least one DRAM module that can be protected in an event of loss of the primary power source.

The above presents a general summary of several aspects of the disclosure in order to provide a basic understanding of at least some aspects of the disclosure. The above summary contains simplifications, generalizations and omissions of detail and is not intended as a comprehensive description of the claimed subject matter but, rather, is intended to provide a brief overview of some of the functionality associated therewith. The summary is not intended to delineate the scope of the claims, and the summary merely presents some concepts of the disclosure in a general form as a prelude to the more detailed description that follows. Other systems, methods, functionality, features and advantages of the claimed subject matter will be or will become apparent to one with skill in the art upon examination of the following figures and detailed written description.

### BRIEF DESCRIPTION OF THE DRAWINGS

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein, in which:

FIG. 1 illustrates a block diagram of an example information handling system (IHS) having dynamic random access memory (DRAM)-based non-volatile dual inline memory modules (NVDIMM) within which various aspects of the disclosure can be implemented, according to one or more embodiments;

FIG. 2 illustrates a block diagram of an example NVDIMM having a dynamically adjustable memory region based on an energy capacity of an independent energy store device, according to one embodiment;

FIG. 3 illustrates a block diagram of a CPU with four (4) memory channels and twelve (12) dual inline memory module (DIMM) slots, according to one embodiment;

FIG. 4 illustrates a flow diagram of a method for adjusting persistent storage by an energy store limited NVDIMM, according to one embodiment;

FIG. 5 illustrates a flow diagram of a method for operating an energy store limited NVDIMM that must be adjusted over time as the energy store degrades, according to one embodiment;

FIG. 6 illustrates a flow diagram of a method for implementing a common energy store limited system supporting multiple NVDIMMs, according to one embodiment;

FIG. 7 illustrates a flow diagram of a method for operating a system that is SAVE/RESTORE time limited, according to one embodiment;

FIG. 8 illustrates an address map of an example NVDIMM, showing persistent and non-persistent memory ranges, according to one embodiment;

FIG. 9 illustrates a diagram of an address map of another example NVDIMM showing persistent and non-persistent memory ranges, according to one embodiment;

FIG. 10 illustrates a diagram of an address map of a set of NVDIMMs powered from a common energy store, showing persistent and non-persistent memory ranges, according to one embodiment; and

FIG. 11 illustrates a flow diagram of a method for dynamically adjusting non-volatile, persistent memory regions of DRAM-based NVDIMM, according to one embodiment.

### DETAILED DESCRIPTION

The illustrative embodiments of the present disclosure provide dynamic random access memory (DRAM)-based non-volatile dual inline memory modules (NVDIMM) with adjustable non-volatile memory regions in order to reduce a size of an independent energy storage device or to accommodate degradations of the independent energy storage device in energy capacity. Taking advantage of the higher speed of a DRAM versus inherently non-volatile memory, an information handling system (IHS) can operate using DRAM during normal operations while providing persistence in the event of unexpected system input power failure. The persistence protects at least a portion of the otherwise volatile memory of DRAM. Adjustment of persistent versus non-persistent memory regions of the DRAM may also be based on a time limit set for save and restore operations in response to loss of a primary power source.

Consider that an amount of supercapacitor or ultracapacitor capacitance required to hold up an NVDIMM through a SAVE operation is growing linearly with NVDIMM memory capacity. This amount of capacitance required already exceeds a physical volume available within a standard server, storage or embedded platform. For example, four (4) 100 F capacitors are required in a 2-series/2-parallel arrangement in order to provide enough energy to perform a SAVE of 8 GB of DRAM to on-DIMM non-volatile flash memory. In some applications, batteries are not acceptable in place of capacitors due to safety concerns, recycling concerns, limitations on recharge cycles, service training implications, and other reasons.

In addition to stored energy considerations, an amount of time required to perform a SAVE operation is also growing linearly with NVDIMM memory capacity. For example, approximately sixty (60) seconds are required per 8 GB of DRAM. Next generation double data rate (DDR) DVDIMMs are expected to be 16-32 GB, and thus require two (2) to four (4) minutes for a SAVE operation, which may exceed allowed time limits.

The present innovation contemplates that NVDIMM customers may not require protection of all of the DRAM-based NVDIMM. Instead, other competing design constraints need to be addressed including the size of independent energy storage devices. In particular, supercapacitors, ultracapacitors, or battery elements exhibit large degradation due to operating temperatures exceeding 40-50° F., high operating voltage, number of charge/recharge cycles, etc., requiring significant “over-provisioning” of as much as 3-10× over 3-5 years. Thus, reducing the required energy storage has a multiplicative benefit on cost, size, and other factors.

In the following detailed description of exemplary embodiments of the disclosure, specific exemplary embodiments in which the disclosure may be practiced are described in sufficient detail to enable those skilled in the art to practice the disclosed embodiments. For example, specific details such as specific method orders, structures, elements, and connections have been presented herein. However, it is to be understood that the specific details presented need not be utilized to practice embodiments of the present disclosure. It is also to be understood that other embodiments may be utilized and that logical, architectural, programmatic, mechanical, electrical and other changes may be made without departing from general scope of the disclosure. The following detailed description is, therefore, not to be taken in a limiting sense, and the scope of the present disclosure is defined by the appended claims and equivalents thereof.

References within the specification to “one embodiment,” “an embodiment,” “embodiments”, or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alternative embodiments mutually exclusive of other embodiments. Further, various features are described which may be exhibited by some embodiments and not by others. Similarly, various requirements are described which may be requirements for some embodiments but not other embodiments.

It is understood that the use of specific component, device and/or parameter names and/or corresponding acronyms thereof, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

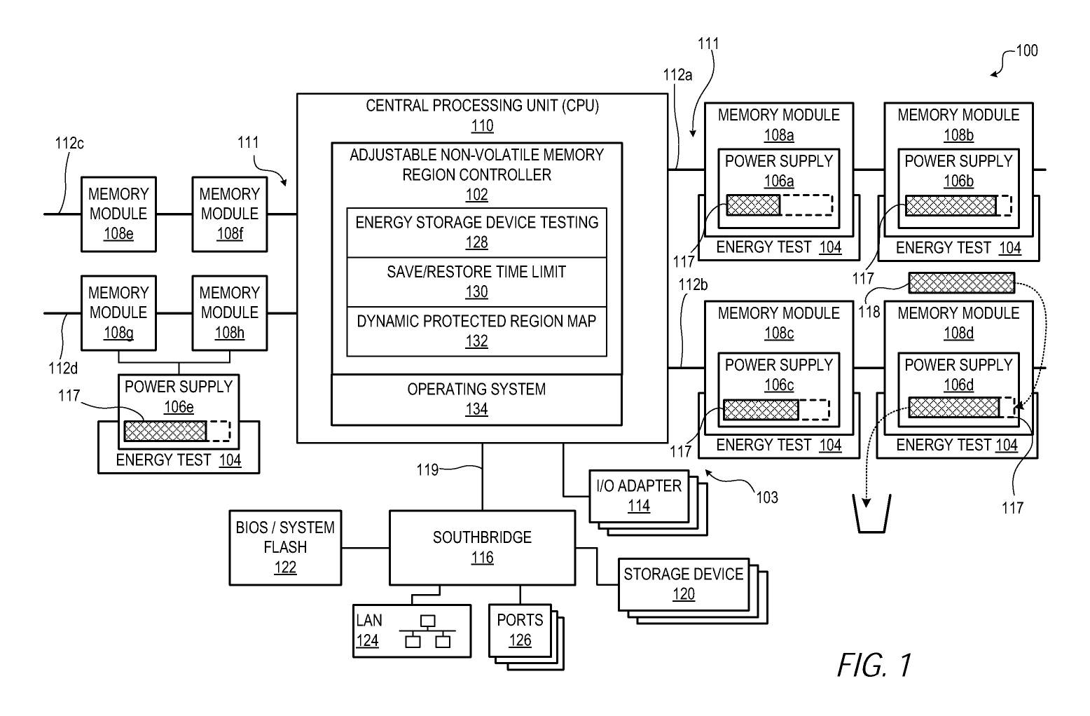

FIG. 1 illustrates a two-dimensional block diagram representation of an example of an information handling system (IHS) 100 within which one or more of the described features of the various embodiments of the disclosure can be implemented. The IHS 100 utilizes volatile memory for execution speed and other benefits, yet protects at least a portion of the volatile memory with persistent memory regions. In particular, these persistent memory regions are DRAM-based non-volatile memory regions with an independent energy storage device. These DRAM-based non-volatile memory regions prevent unacceptable loss of data or processes via SAVE and RESTORE operations. In particular, the IHS 100 adjusts non-volatile memory regions at least in part based on an energy capacity of an independent energy storage device. As a two-dimensional image, certain of the presented components are shown in different orientations relative to each other for simplicity in describing the connectivity of the components. For purposes of this disclosure, an information handling system, such as IHS 100, may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a handheld device, personal computer, a server, a network storage device, or any other suitable device and may vary in size, shape, performance, functionality, and price. The information handling system may include random access memory (RAM), one or more processing resources such as a central processing unit (CPU) or hardware or software control logic, read only memory (ROM), and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

IHS 100 includes central processing unit (CPU) 110 which is coupled to a plurality of memory modules 108a-h via a series of interconnects 103. IHS 100 also includes input/output (I/O) adapters 114 and southbridge 116 both coupled to CPU 110. CPU 110 includes controller 102 for adjusting non-volatile memory regions of the IHS 100 that may be implemented in hardware, software or in software. The controller 102 is assisted by energy test hardware 104 resident as part of a power supply 106a-106e that serves as an independent energy storage device for one or more memory modules 108a-108h. Memory modules 108a-108d may be implemented as double data rate (DDR) DRAM NVDIMMs or other suitable memory technology, each with an integral or tethered power supply 106a-106d, respectively. For example, the independent energy storage device may connect via a dedicated connector interface or may be electrically connected via power pins on an NVDIMM socket connector through a system board. Memory modules 108e-108f do not have a power supply that serves as an independent energy storage device. Memory modules 108g-108h are both supported by a single power supply 106e. Power supplies 106a-e may be implemented as batteries, UltraCapacitors, or any other suitable energy storage device that provides the required power over the required hold-up (SAVE) time. Central processing unit (CPU) 110 is coupled over a memory bus 111 with the memory modules 108a-108b over a first channel 112a, with the memory modules 108c-108d over a second channel 112b, with the memory modules 108e-108f over a third channel 112c, and with the memory modules 108g-108h over a fourth channel 112d. CPU 110 can also be coupled to Input/Output (I/O) adapters 114 via Peripheral Component Interconnect (PCIe) other other suitable interconnect.

Power supplies 106a-106e each may have a different energy capacity 117. For example, the power supplies 106a-106e may be serviced by replaceable batteries 118. For example, IHS 100 may adjust the non-volatile protected region/s to compensate for the actual/measured capability of the detected energy source after a new energy source has been hot-added, hot-replaced, or hot-upgraded. The added energy source may be detected via a PRESENT line, polling, interrupt, or many other mechanisms.

A southbridge 116 is coupled to the CPU 110 by way of a system bus 119. The system bus 119 may be implemented as a PCI Express bus. For clarity, it should be understood that a northbridge may implemented as part of the CPU 110 to interface to the southbridge 116. Certain embodiments may implement features of the southbridge 116 as part of a platform controller hub (PCH) or similar implementations. IHS 100 can include storage devices 120. The storage devices 120 may be connected to the southbridge 116 using a variety of interfaces, such as Serial ATA (SATA) or Serial Attached SCSI (SAS), wherein ATA refers to Advanced Technology Attachment and SCSI refers to Small Computer System Interface. Basic Input/Output System (BIOS)/system flash 122 is connected to the southbridge 116. Southbridge 116 can also be coupled to an Ethernet/Local Access Network (LAN) 124 and to Universal Serial Bus (USB) ports 126.

In one embodiment, the controller 102 for adjusting non-volatile memory regions includes an energy storage device testing utility 128 that may reference save/restore time limit value 130 and update a dynamic protected region map 132. The energy storage device testing utility 128 can execute on an operating system 134 to cause the IHS 100 to determine a persistent value. The persistent value corresponds to a fraction of memory space of the at least one DRAM module. This fraction that can be protected is based at least in part upon the measured energy capacity value for the independent energy storage device provided by a respective power supply 106a-106e. The energy storage device utility 128 reports the persistent value to the host processor.

For example, the region/s within the DRAM capacity that require SAVE/RESTORE may be provided through a list of memory region segments, a linked list, a bitmap, or any other suitable mechanisms that describe which portion of the NVDIMM are to be SAVED and which are not to be SAVED. IHS 100 may change the memory regions dynamically during system operations provided that the operations are guarded and “atomic”. The IHS 100 may provide a dynamic assignment of persistent and non-persistent memory allocations as region information in-band over the DDR channel to special purpose control and status registers (CSRs), via SMBus interface to the NVDIMM, or through a custom interface to the NVDIMM. In one embodiment, the controller 102 is initiated with a default setting. For example, the default setting may be chosen to be one of (a) no memory is SAVED, (b) all memory is SAVED or (c) any other desired fraction of memory is SAVED.

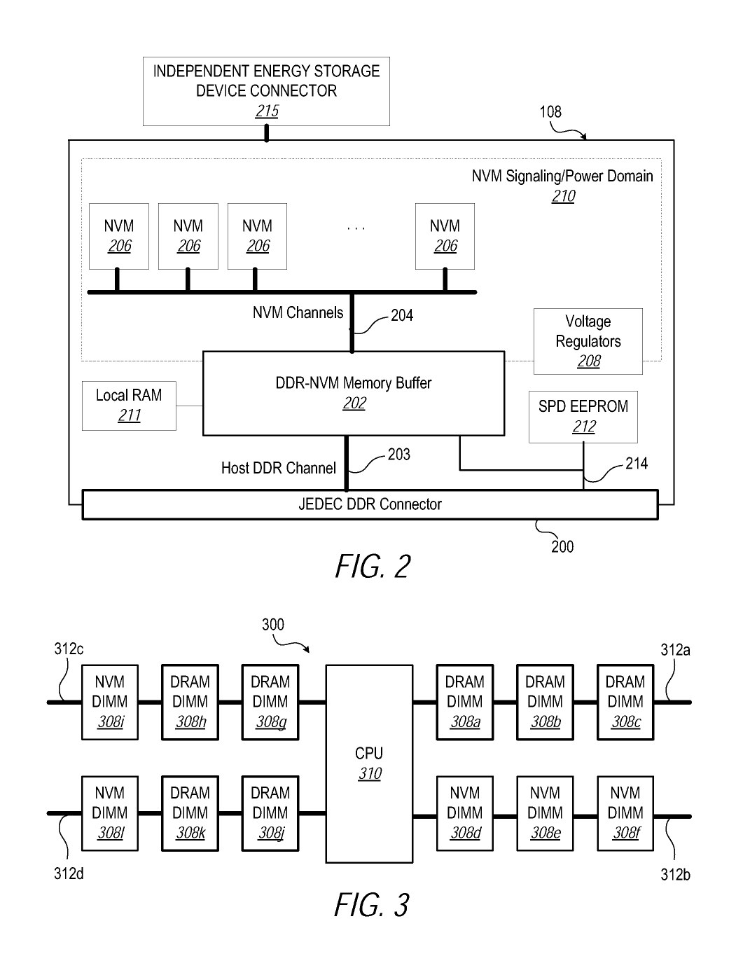

FIG. 2 illustrates an example memory module 108 implemented as an NVDIMM that couples to the CPU 110 (FIG. 1) via a JEDEC DDR connector 200, wherein JEDEC refers to the Joint Electron Device Engineering Council (now the JEDEC Solid State Technology Association). DDR-NVM memory buffer 202 couples via a host DDR channel 203 to the JEDEC DDR connector 200 and via NVM channels 204 to NVMs 206 that are biased by voltage regulators 208 and reside within an NVM signaling/power domain 210. NVMs 206 may be volatile DRAMs with associated SAVE energy back-up power, or any other suitable memory technology. SAVE energy back-up power may be implemented via batteries, UltraCapacitors, or other suitable energy source capable of supplying the required power for the duration of the SAVE operation. DDR-NVM memory buffer 202 may optionally couple to local RAM 211. Serial presence detect (SPD) electrically erasable programmable read-only memory (EEPROM) 212 is coupled via a system management bus (SMBus) 214 to the DDR-NVM memory buffer 202 and the JEDEC DDR connector 200. SPD EEPROM 212 provides a standardized way to automatically access information about the memory module 108, such as during power-on self-test (POST), to automatically configure the hardware currently present. The memory module 108 includes an independent energy storage device connector 215. that can be connected to battery, Ultracapacitor or other independent energy storage device to provide power during a SAVE operation.

FIG. 3 illustrates an IHS 300 with four (4) memory channels 312a-312d coupled to a CPU 310. Twelve (12) DIMM slots are populated from inboard to outboard as DRAM DIMMs 308a-308c on first channel 312a, NVM DIMMs 308d-308f on second channel 312b, DRAM DIMMs 308g-308h and NVM DIMM 308i on third channel 312c, and DRAM DIMMs 308j-308k and NVM DIMM 3081 on fourth channel 312d. In other embodiments, the number of memory channels, number of DRAM DIMMs, number of NVM DIMMs, and the population order of the various DIMMs may be different.

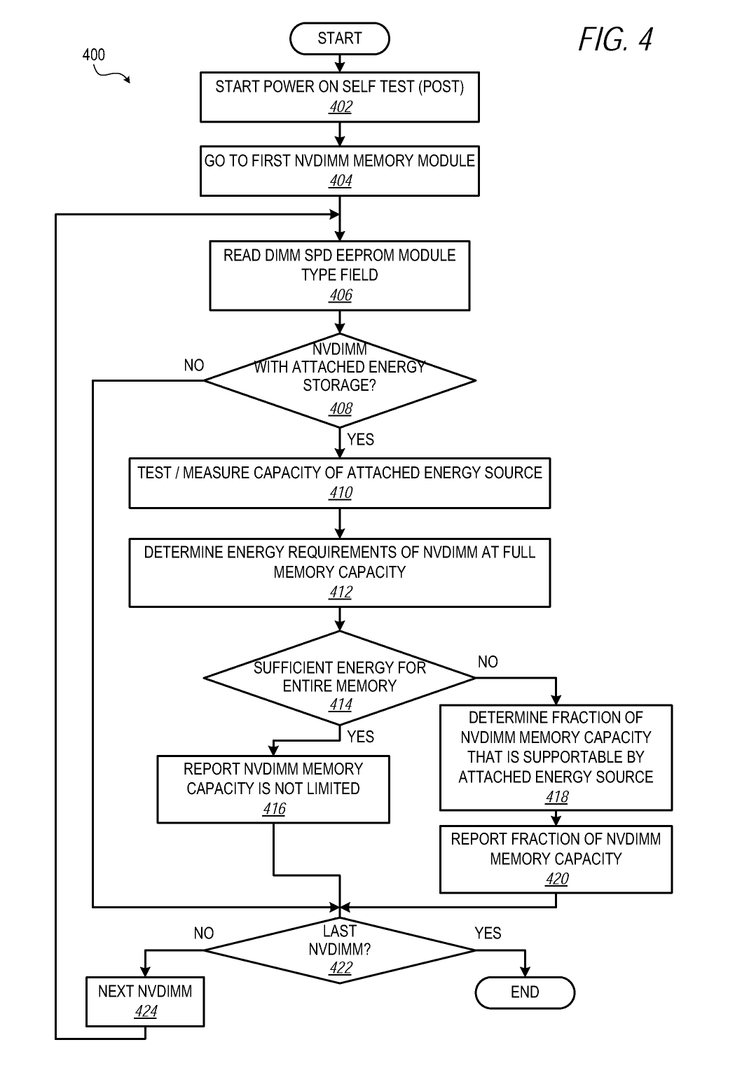

FIG. 4 illustrates a method 400 for adjusting persistent storage by an energy store limited NVDIMM, according to one embodiment. In block 402, the method 400 includes starting a power-on self-test (POST). A controller goes to the first NVDIMM memory module (block 404). The controller reads DIMM SPD EEPROM module type field (block 406). In decision block 408, the controller determines whether the type field indicates that the NVDIMM is with an attached energy storage device. In response to the determination that the NVDIMM is with an attached energy storage device in decision block 408, the controller causes a test or measurement of an energy capacity of the attached energy source in block 410. In block 412, the controller determines energy requirements of the NVDIMM at full memory capacity. In decision block 414, a determination is made as to whether the measured capacity is sufficient energy for the entire memory requirements of the NVDIMM. In response to a determination in decision block 414 of sufficient energy for the entire memory requirements, then in block 416 the controller reports NVDIMM memory capacity is not limited. In response to a determination in decision block 414 of insufficient energy for the entire memory requirements, then in block 418 the controller determines what fraction of NVDIMM memory capacity is supportable by the attached energy source. The controller reports the fraction of NVDIMM memory capacity that is supportable (block 420).

In response to one of (a) a determination in decision block 408 that NVDIMM did not have an attached energy storage device, or (b) after the controller reports NVDIMM memory capacity is not limited in block 416, or (c) after the controller reports the fraction of NVDIMM memory capacity that is supportable in block 420, then a determination is made in decision block 422 as to whether the NVDIMM is the last NVDIMM. In response to a determination in decision block 422 that the NVDIMM is the last NVDIMM, method 400 ends. In response to a determination in decision block 422 that the NVDIMM is not the last NVDIMM, the next NVDIMM is found (block 424) and processing returns to block 406 to repeat the testing.

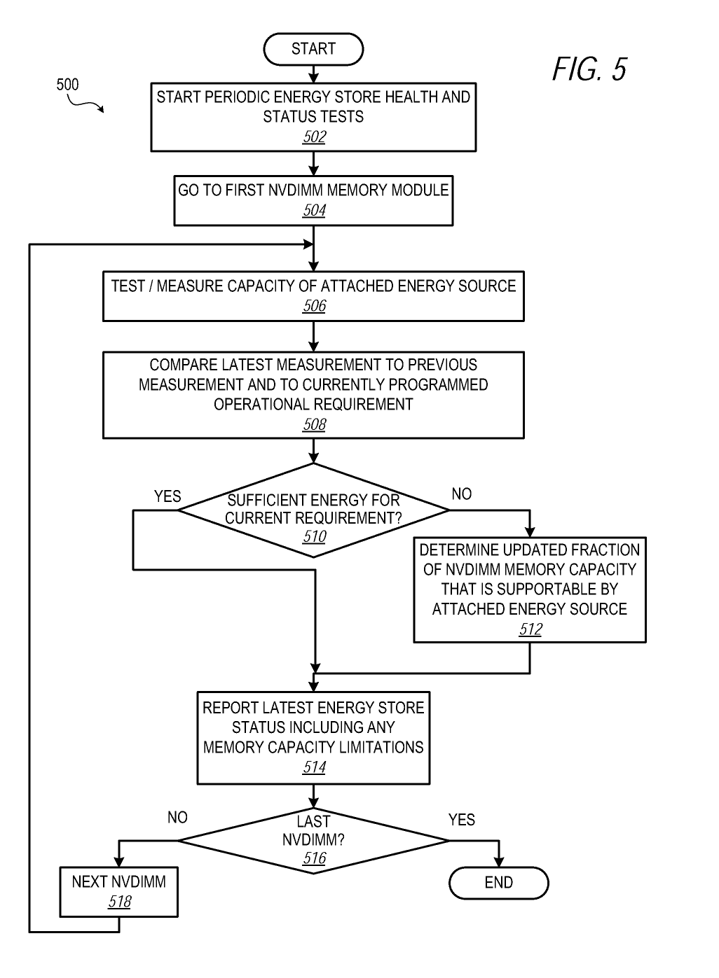

FIG. 5 illustrates a flow diagram of a method for operating an energy store limited NVDIMM that must be adjusted over time as the energy store degrades, according to one embodiment. In block 502, the method 500 includes a periodic energy store health and status tests. A controller goes to the first NVDIMM memory module (block 504). The controller causes a test or measurement of an energy capacity of the attached energy source in block 506. In block 508, the controller compares latest measurement to previous measurement and to currently programmed operational requirement. In decision block 510, a determination is made as to whether the measured capacity is sufficient energy for performing a SAVE operation for the current persistent memory assignment, of the NVDIMM, which is the current operation requirement. In response to a determination in decision block 510 that there is insufficient energy to perform a SAVE operation for the current persistent memory assignment, then in block 512 the controller determines what fraction of NVDIMM memory capacity is supportable by the attached energy source. In response to a determination in decision block 510 of sufficient energy for the operational requirement or after determining the updated fraction in block 512, the controller reports latest energy store status including any memory capacity limitations to the operating system and/or user application (block 514). A determination is made in decision block 516 as to whether the NVDIMM is the last NVDIMM. In response to a determination in decision block 516 that the NVDIMM is the last NVDIMM, method 500 ends. In response to a determination in decision block 516 that the NVDIMM is not the last NVDIMM, then the next NVDIMM is found (block 518) and processing returns to block 506 to repeat the testing.

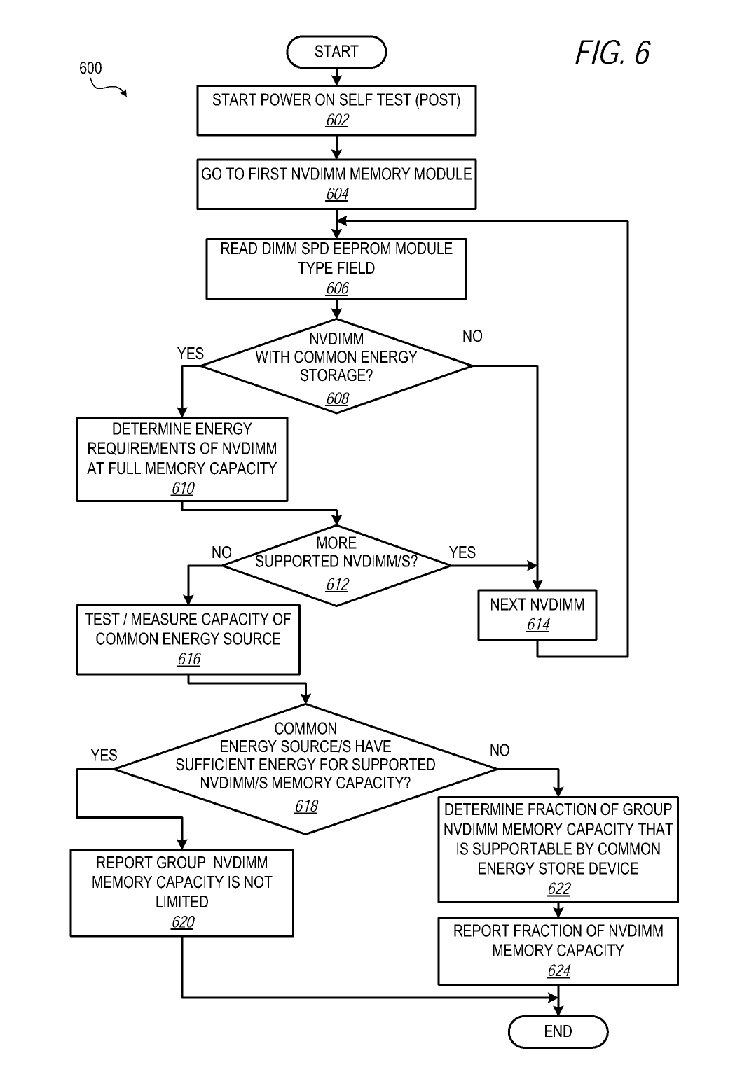

FIG. 6 illustrates a method 600 of implementing a common energy store limited system supporting multiple NVDIMMs, according to one embodiment. In block 602, the method 600 includes starting a power on self-test (POST). A controller goes to the first NVDIMM memory module (block 604). The controller reads the DIMM SPD EEPROM module type field (block 606). In decision block 608, the controller determines whether the type field indicates that the NVDIMM is with a common energy storage device. A common energy storage device may be cabled to a plurality of NVDIMMs 108 directly, or indirectly distributed to the NVDIMM to system board connector interfaces 200. In response to the determination in decision block 608 that the NVDIMM is with a common energy storage device, the controller determines energy requirements of the NVDIMM at full memory capacity (block 610). Then a determination is made in decision block 612 as to whether more NVDIMM/s are supported by the same common energy storage device. In response to the determination that more NVDIMM/s are supported by the same attached energy storage device in decision block 612, then the next NVDIMM is located in block 614 and processing returns to block 606 to continue determining memory requirements for the common energy storage device.

In response to a determination in decision block 612 that there are no more NVDIMMs supported by the same common energy storage device, then the controller causes a test or measurement of an energy capacity of the common energy source in block 616. In decision block 618, a determination is made as to whether the measured capacity is sufficient energy for the entire memory requirements of all of the populated NVDIMMs. In response to a determination in decision block 618 that there is sufficient energy for the entire memory requirements, in block 620 the controller reports that group NVDIMM memory capacity is not limited. In response to a determination in decision block 618 that there is insufficient energy for the entire group memory requirements, in block 622 the controller determines what fraction of group NVDIMM memory capacity is supportable by the common energy storage device. The controller reports the fraction of group NVDIMM memory capacity that is supportable (block 624). After reporting in either block 620 or block 624, method 600 ends.

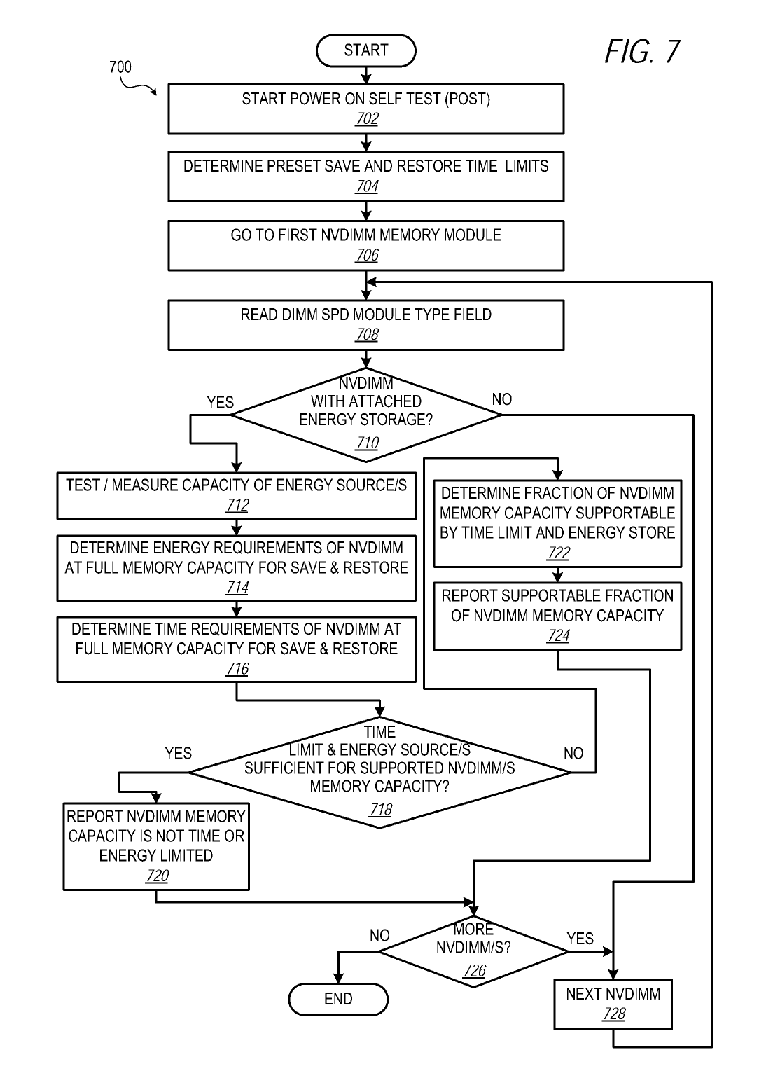

FIG. 7 illustrates a method 700 for operating an IHS that is SAVE/RESTORE time limited, according to one embodiment. In block 702, the method 700 includes starting a power on self-test (POST). A controller retrieves or determines preset SAVE and RESTORE time limits (block 704). The preset limits may be previously set by system firmware, operating system, user application, user command, or other suitable method. The controller goes to the first NVDIMM memory module (block 706). The controller reads DIMM SPD EEPROM module type field (block 708). In decision block 710, the controller determines whether the type field indicates that the NVDIMM is with an attached energy storage device. In response to the determination in decision block 710 that the NVDIMM is with an attached energy storage device, the controller causes a test or measurement of an energy capacity of the attached energy source in block 712. In block 714, the controller determines energy requirements of NVDIMM at full memory capacity for save and restore. In block 716, the controller determines time requirements of NVDIMM at full memory capacity for save and restore.

In decision block 718, a determination is made as to whether the measured capacity is sufficient energy and the time limit is sufficient for the entire memory requirements of the NVDIMM. In response to a determination in decision block 718 that there is sufficient energy and time for the entire memory requirements, in block 720 the controller reports NVDIMM memory capacity is not time or energy limited. In response to a determination in decision block 718 that there is insufficient energy or time for the entire memory requirements, in block 722 the controller determines what fraction of NVDIMM memory capacity is supportable by the attached energy storage device within the time limits. The controller reports the fraction of NVDIMM memory capacity that is supportable (block 724).

In response to one of (a) a determination in decision block 710 that NVDIMM did not have an attached energy storage device, or (b) after the controller reports NVDIMM memory capacity is not time or energy limited in block 720, or (c) after the controller reports the fraction of NVDIMM memory capacity that is supportable in block 724, a determination is made in decision block 726 as to whether the NVDIMM is the last NVDIMM. In response to a determination in block 726 that the NVDIMM is the last NVDIMM, then method 700 ends. In response to a determination in block 726 that the NVDIMM is not the last NVDIMM, then the next NVDIMM is found (block 728) and processing returns to block 708 to repeat the testing.

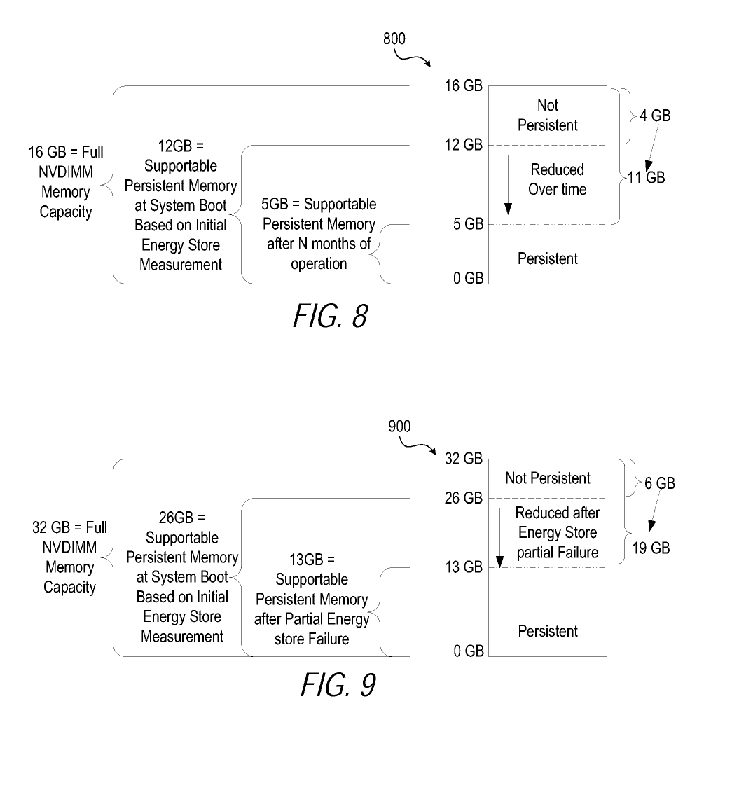

FIG. 8 illustrates an address map 800 of an example 16 GB NVDIMM illustrating a 4 GB memory region that is not persistent increasing to 11 GB over time, as a 12 GB persistent memory region conversely reduces over time to 5 GB. The supportable persistent memory is reduced periodically and incrementally due to the degradation of energy hold-up capacity over time.

FIG. 9 illustrates another example address map 900 of a 32 GB NVDIMM illustrating a 6 GB memory region that is not persistent and which increases to 19 GB immediately, as a 26 GB persistent memory region conversely reduces immediately to 13 GB, after a partial failure of the energy store is detected.

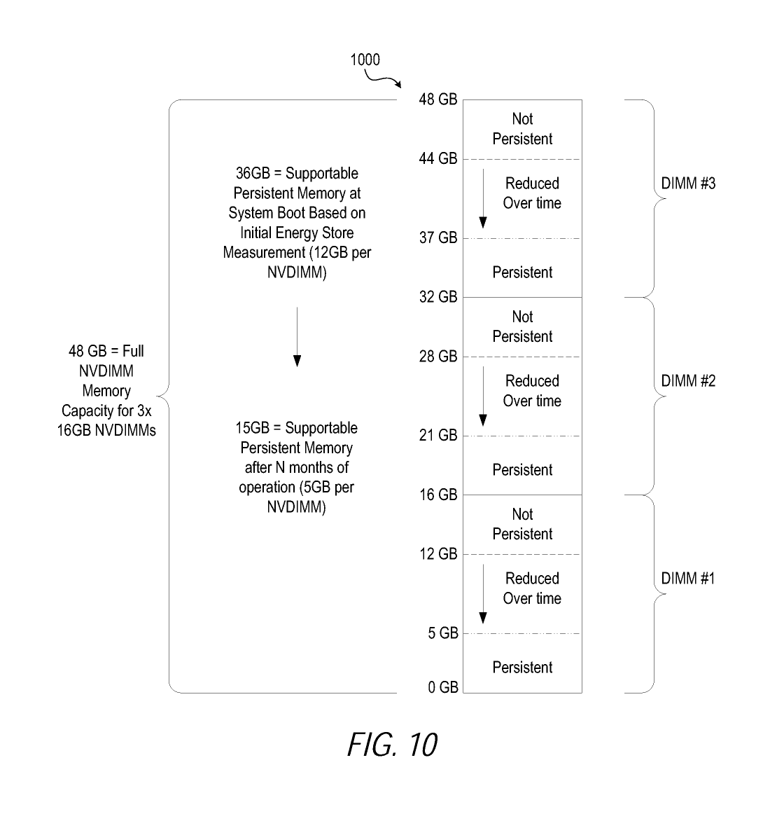

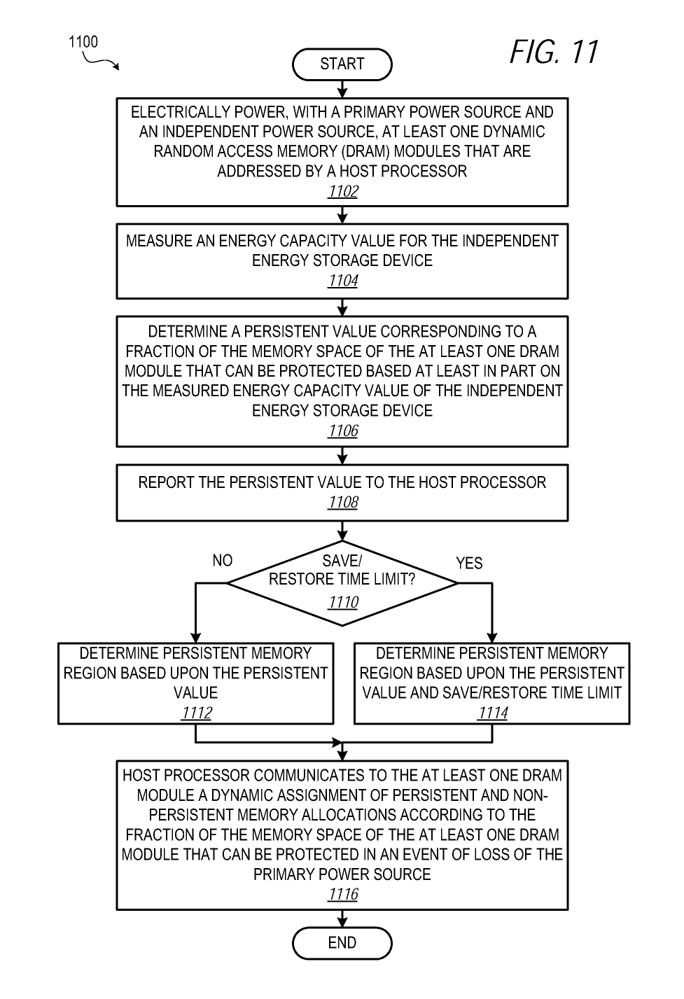

FIG. 10 illustrates an address map 1000 of a set of NVDIMMs 1-3 powered from a common energy storage device showing persistent and non-persistent memory ranges that change from 36 GB supportable persistent and 12 GB non-persistent to 15 GB supportable persistent and 33 non-persistent.

FIG. 11 illustrates a method 1100 for dynamically adjusting non-volatile, persistent memory regions of DRAM-based NVDIMM, according to one embodiment. In block 1102, the method 1100 includes electrically powering, with a primary power source and an independent power source, at least one DRAM module having an amount of memory space that is addressed by a host processor of an IHS. A controller measures an energy capacity value of the independent energy storage device (block 1104). In block 1106, the controller determines a persistent value corresponding to a fraction of the memory space of the at least one DRAM module that can be protected, based at least in part on the measured energy capacity value of the independent energy storage device. The controller reports the persistent value to the host processor in block 1108. In decision block 1110, a determination is made as to whether a save/restore time limit may impose a limit on the size of the persistent memory region that is more constraining than the energy capacity of the independent energy storage device. In response to determining that a save/restore time limit does not exist, then a controller determines a persistent memory region based on persistent value of the energy stored (block 1112). In response to determining that a save/restore time limit exists, then the controller determines a persistent memory region based on the persistent value of the energy stored and the save/restore time limit (block 1114). In block 1116, a host processor communicates to the at least one DRAM module a dynamic assignment of persistent and non-persistent memory allocations. The dynamic assignment is made according to the fraction of the memory space of the at least one DRAM module that can be protected in an event of loss of the primary power source. Then method 1100 ends.

In the above described flow charts of FIGS. 4-7 and 11, one or more of the methods may be embodied in a manufacturing device/s such that a series of functional processes are performed in an automated assembly line. In some implementations, certain steps of the methods are combined, performed simultaneously or in a different order, or perhaps omitted, without deviating from the scope of the disclosure. Thus, while the method blocks are described and illustrated in a particular sequence, use of a specific sequence of functional processes represented by the blocks is not meant to imply any limitations on the disclosure. Changes may be made with regards to the sequence of processes without departing from the scope of the present disclosure. Use of a particular sequence is therefore, not to be taken in a limiting sense, and the scope of the present disclosure is defined only by the appended claims.

One or more of the embodiments of the disclosure described can be implementable, at least in part, using a software-controlled programmable processing device, such as a microprocessor, digital signal processor or other processing device, data processing apparatus or system. Thus, it is appreciated that a computer program for configuring a programmable device, apparatus or system to implement the foregoing described methods is envisaged as an aspect of the present disclosure. The computer program may be embodied as source code or undergo compilation for implementation on a processing device, apparatus, or system. Suitably, the computer program is stored on a carrier device in machine or device readable form, for example in solid-state memory, magnetic memory such as disk or tape, optically or magneto-optically readable memory such as compact disk or digital versatile disk, flash memory, etc. The processing device, apparatus or system utilizes the program or a part thereof to configure the processing device, apparatus, or system for operation.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular system, device or component thereof to the teachings of the disclosure without departing from the essential scope thereof. Therefore, it is intended that the disclosure not be limited to the particular embodiments disclosed for carrying out this disclosure, but that the disclosure will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The description of the present disclosure has been presented for purposes of illustration and description, but is not intended to be exhaustive or limited to the disclosure in the form disclosed. Many modifications and variations will be apparent to those of ordinary skill in the art without departing from the scope of the disclosure. The described embodiments were chosen and described in order to best explain the principles of the disclosure and the practical application, and to enable others of ordinary skill in the art to understand the disclosure for various embodiments with various modifications as are suited to the particular use contemplated.

What is claimed is:

1. An information handling system comprising:
a host processor powered by a primary power source;
at least one dynamic random access memory (DRAM) module having a memory space addressed by the host processor;
an independent energy storage device electrically connected to the at least one DRAM module;
an energy test component that measures an energy capacity value for the independent energy storage device; and
a controller that: determines a persistent value corresponding to a fraction of the memory space of the at least one DRAM module that can be protected based at least in part upon the measured energy capacity value for the independent energy storage device; and reports the persistent value to the host processor;
wherein the host processor communicates to the at least one DRAM module a dynamic assignment of persistent and non-persistent memory allocations in accordance to the fraction of the memory space of the at least one DRAM module that can be protected in an event of loss of the primary power source.

2. The information handling system of claim 1, wherein one of the host processor and the controller determines the persistent memory region based at least in part on a maximum time limit set for save and restore operations in response to loss of the primary power source.

3. The information handling system of claim 1, wherein the host processor:
reassigns the persistent memory allocation of the at least one DRAM module to an non-persistent status;
initiates a retest by the energy test component of the independent energy storage device;
determines an updated persistent value of the at least one DRAM module; and
allocates an updated persistent memory allocation of the at least one DRAM module.

4. The information handling system of claim 3, wherein the host processor further:
detects that a new energy storage device is supporting the at least one DRAM module; and
initiates the retest in response to the detected new energy storage device.

5. The information handling system of claim 1, wherein the controller further:
determines a time limit set for save and restore operations of the at least one DRAM module; and
determines the fraction of the memory space of the at least one DRAM module that can be protected based on a smaller value imposed by either the time limit and the measured energy capacity.

6. The information handling system of claim 1, wherein the at least one DRAM module supported by the independent energy storage device communicate on a first channel to the host processor, the information handling system further comprising at least one other DRAM module that is supported by a second independent energy storage device on a second channel.

7. The information handling system of claim 1, wherein the independent energy storage device supports at least two DRAM modules.

8. The information handling system of claim 1, wherein the energy test component is in electrical communication with the independent energy storage device and measures the energy capacity value utilizing one of a battery gauge, a capacitance measuring device, and a voltage measuring device, and a slew rate measuring device.

9. A method, comprising:
electrically powering, with a primary power source and an independent power source, at least one dynamic random access memory (DRAM) module having a memory space that is addressed by a host processor of an information handling system;
measuring an energy capacity value of the independent energy storage device;
determining a persistent value corresponding to a fraction of the memory space of the at least one DRAM module that can be protected based at least in part on the measured energy capacity value of the independent energy storage device;
reporting the persistent value to the host processor; and
communicating by the host processor to the at least one DRAM module a dynamic assignment of persistent and non-persistent memory allocations in accordance to the fraction of the memory space of the at least one DRAM module that can be protected in an event of loss of the primary power source.

10. The method of claim 9, further comprising determining the persistent memory region based at least in part upon a maximum time limit set for save and restore operations in response to loss of the primary power source.

11. The method of claim 9, further comprising:
reassigning the persistent memory allocation of the at least one DRAM module to a non-persistent status;
initiating a retest by the energy test component of the independent energy storage device; and
determining an updated energy capacity of the DRAM module; and
allocating an updated persistent memory allocation of the at least one DRAM module based upon the updated energy capacity.

12. The method of claim 11, further comprising:
detecting that a new energy storage device is supporting the at least one DRAM module; and
initiating the retest in response to detecting the new energy storage device.

13. The method of claim 9, further comprising:
determining a time limit set for save and restore operations of the one or more DRAM modules in response to loss of the primary power source; and
determining the fraction of the memory space of the at least one DRAM module that can be protected based on a smaller value imposed by either the time limit and the measured energy capacity.

14. The method of claim 9, further comprising:
the host processor communicating on a first channel to the at least one DRAM module that is supported by the independent energy storage device; and
the host processor communicating on a second channel to another DRAM module that is supported by a second independent energy storage device.

15. The method of claim 9, further comprising supporting at least two DRAM modules by the independent energy storage device.

16. The method of claim 9, further comprising measuring the energy capacity value utilizing one of a battery gauge, a capacitance measuring device, and a voltage measuring device, and a slew rate measuring device.
